(19) United States
(12) Patent Application Publication
(10) Pub. No.: US 2026/0291276 A1
(43) Pub. Date: Sep. 24, 2026

(54) ENERGY CONTROL METHOD AND CONTROLLER FOR ENERGY MANAGEMENT

(71) Applicant: Wistron Corporation, New Taipei City (TW)

(72) Inventors: Cheng I Chen, Taoyuan (TW); Hsueh Yi Tung, Taoyuan (TW)

(73) Assignee: Wistron Corporation, New Taipei City (TW)

(21) Appl. No.: 19/203,217

(22) Filed: May 9, 2025

(30) Foreign Application Priority Data
Mar. 20, 2025 (TW) 114110595

(51) Int. Cl. H02J 13/00; G05B 15/02; H03H 17/02

(52) U.S. Cl. CPC H02J 13/12; G05B 15/02; H03H 17/02

(57) ABSTRACT

An energy control method and a controller for energy management are provided. In the method, a first output power of a target energy source within a monitoring time interval is obtained. A second output power of the target energy source within an extended time interval is determined. The extended time interval corresponds to a time interval after the monitoring time interval. Filter weights are determined based on the first output power and the second output power. The filter weights are used for smoothing filtering. The first output power and the second output power are smoothed based on the filter weights. Thereby, the degree of smoothing control may be improved and time delay may be reduced.

### CROSS-REFERENCE TO RELATED APPLICATION

This application claims the priority benefit of Taiwan application serial no. 114110595, filed on Mar. 20, 2025. The entirety of the above-mentioned patent application is hereby incorporated by reference herein and made a part of this specification.

### BACKGROUND

### Technical Field

This disclosure relates to an energy management technology, and particularly relates to an energy control method and a controller for energy management.

### Description of Related Art

In recent years, global attention to the development and application of renewable energy has been increasing, especially solar photovoltaics (PV) technology. However, solar power generation has intermittent characteristics, which may cause problems such as failures or power outages in the electricity system. Therefore, combining Battery Energy Storage System (BESS) to improve the stability of the electricity network has become a solution.

Due to regulatory restrictions and the high cost of energy storage systems, using smoothing filters combined with battery energy storage systems to reduce costs and stabilize output power has become a method that has received widespread attention. However, existing filters can effectively smooth power fluctuations, but they bring significant time delays.

### SUMMARY

The disclosure provides an energy control method and a controller for energy management, capable of effectively reducing time delay.

The energy control method of the embodiment of the disclosure includes (but is not limited to) the following. A first output power of a target energy source in a monitoring time interval is obtained. A second output power of the target energy source in an extended time interval is determined, wherein the extended time interval corresponds to a time interval after the monitoring time interval. A filter weight is determined according to the first output power and the second output power, wherein the filter weight is configured to smooth filtering. The first output power and the second output power are smoothed according to the filter weight.

The controller for energy management of the embodiment of the disclosure is configured to: obtain a first output power of a target energy source in a monitoring time interval; determine a second output power of the target energy source in an extended time interval; determine a filter weight according to the first output power and the second output power. The extended time interval corresponds to a time interval after the monitoring time interval, and the filter weight is configured to smooth filtering.

Based on the above, the energy control method and the controller for energy management of the embodiment of the disclosure expand the output power (i.e., the second output power) after the monitoring time interval, and smooth the original output power (i.e., the first output power) and the expanded output power. Thereby, the boundary problem of the filter may be solved, and the filtering delay may be reduced.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a component block diagram of an overall system according to an embodiment of the disclosure.

FIG. 2 is a schematic diagram of renewable energy control according to an embodiment of the disclosure.

FIG. 3 is a flowchart of an energy control method according to an embodiment of the disclosure.

FIG. 4 is a schematic diagram of a gaussian filter according to an embodiment of the disclosure.

FIG. 5 is a schematic diagram of signal expansion according to an embodiment of the disclosure.

FIG. 6 is a flowchart of improved gaussian filter smoothing according to an embodiment of the disclosure.

FIG. 7 is a flowchart of energy storage power control according to an embodiment of the disclosure.

FIG. 8 is a comparison diagram between the improved gaussian filter and moving average methods of an embodiment of the disclosure.

FIG. 9 is a comparison diagram between the improved gaussian filter and double moving average methods of an embodiment of the disclosure.

FIG. 10 is a comparison diagram between the improved gaussian filter and exponential moving average methods of an embodiment of the disclosure.

### DESCRIPTION OF THE EMBODIMENTS

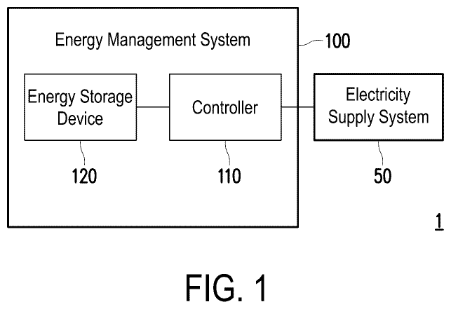

FIG. 1 is a component block diagram of an overall system 1 according to an embodiment of the disclosure. Referring to FIG. 1, the overall system 1 includes (but is not limited to) an electricity supply system 50 and an energy management system 100.

The electricity supply system 50 exemplifies various types of power generation systems, power converters, generators, or other devices that provide electricity or combinations of multiple devices. The electricity supply system 50 may provide electricity through target energy source. In one embodiment, the target energy source exemplifies solar energy, wind power energy, hydroelectric power energy, or other renewable energy/green electricity. In another embodiment, the target energy source may also be thermal power energy or nuclear energy. The type of target energy source may vary according to different design requirements, and the embodiment of the disclosure does not impose limitations on this.

The energy management system 100 includes (but is not limited to) a controller 110 and an energy storage device 120.

The controller 110 may be a mobile phone, tablet computer, laptop computer, desktop computer, server, voice assistant device, smart home appliance, wearable device, vehicle system, or other electronic device. Alternatively, the controller 110 may be a Central Processing Unit (CPU), Graphic Processing Unit (GPU), or other programmable general-purpose or special-purpose microprocessor, Digital Signal Processor (DSP), programmable controller, Field Programmable Gate Array (FPGA), Application-Specific Integrated Circuit (ASIC), neural network accelerator, or other similar components or combinations of the above components.

In some application scenarios, the controller 110 may be referred to as a smoothing controller.

The energy storage device 120 is coupled to the controller 110. The energy storage device 120 may be a Battery Energy Storage System (BESS), super capacitor energy storage system, or hybrid energy storage system.

In some application scenarios, the energy storage device 120 is also coupled to other electricity networks and the electricity supply system 50. The energy storage device 120 may supply/discharge to the electricity network, and/or the electricity supply system 50 may charge the energy storage device 120.

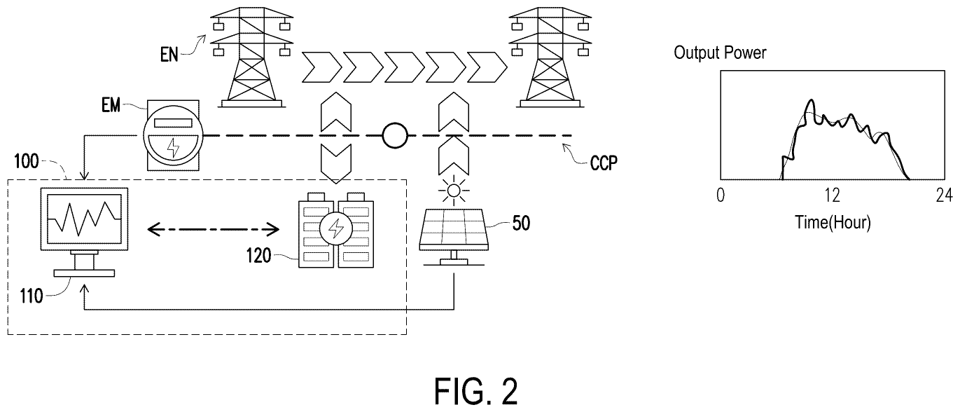

FIG. 2 is a schematic diagram of renewable energy control according to an embodiment of the disclosure. Referring to FIG. 2, in a renewable energy application scenario, the electricity supply system 50 exemplifies a solar power generation system. The electricity supply system 50 and the energy storage device 120 are respectively coupled to an electricity network EN (for example, a public electricity network) through a common coupling point CCP. The controller 110 may capture output power provided by the electricity supply system 50 through the common coupling point CCP. As shown in the figure, the output power is captured within 24 hours. The controller 110 may control the energy storage device 120 to perform charging or discharging operations. The charging source exemplifies the electricity supply system 50 and/or the electricity network EN. The discharge target exemplifies the electricity network EN.

It should be noted that the above application scenario is only provided as an example, and users may change the devices or functions according to actual requirements.

In the following, the method described in the embodiment of the disclosure will be explained with the various systems, devices, components, and modules in the overall system 1. Each process of this method may be adjusted along with the implementation circumstances, and is not limited to this.

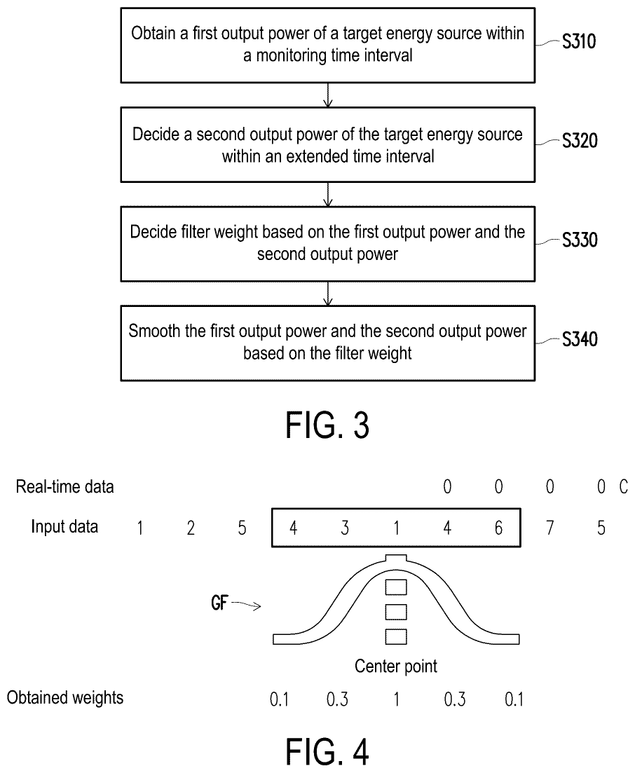

FIG. 3 is a flowchart of an energy control method according to an embodiment of the disclosure. Referring to FIG. 3, the controller 110 obtains a first output power of the target energy source within a monitoring time interval (step S310). Specifically, the target energy source exemplifies the energy provided by the electricity supply system 50. The target energy source is used to generate electricity. The monitoring time interval may be 5 minutes, 30 minutes, 1 hour, 12 hours, or 24 hours, and is not limited to these. As shown in FIG. 2, the controller 110 may capture the output power of the electricity supply system 50 within 24 hours through an electric meter EM. The methods for obtaining/measuring/capturing the value of the output power exemplify sensor measurement, parsing packets in the communication protocol of the power system, or recording power data through a data acquisition system.

In an embodiment, the first output power within the monitoring time interval may include multiple first power values corresponding to multiple sample points.

The controller 110 determines a second output power of the target energy source within an extended time interval (step S320). Specifically, the first output power obtained/measured/captured by the controller 110 within the monitoring time interval includes the latest output power. The latest output power may be the output power obtained at the last/most recent sampling time point or capture time point within the monitoring time interval. That is, the latest output power may represent the real-time/current time output power of the target energy source. The extended time interval corresponds to the time interval after the monitoring time interval. That is, the extended time interval represents a future time interval corresponding to the current time.

In an embodiment, the second output power within the extended time interval may include multiple second power values corresponding to multiple sample points.

The following further explains why to obtain the second output power within the extended time interval.

It is worth noting that Ramp Rate (RR) is used to measure the degree of power variation of renewable energy systems such as solar energy systems or wind energy systems within a unit time:

RR=|ΔP|/ΔT (%/minute) (1),

where ΔP is the amount of power change over time, ΔT is the time required for the change, with the unit being minutes. Ramp rate is commonly used to evaluate the stability and reliability of energy systems, and to determine system operating limitations and regulation strategies. Currently, the common international standard range for power ramp rates of solar energy systems is 4~10% per minute, meaning that the output power of the system can increase or decrease by a maximum of 4~10% per minute in a short time. In order to reduce the impact of intermittent power generation from renewable energy sources causing rapid power fluctuations on the electricity network, it is necessary to smooth the output power of renewable energy power converters at the point of common coupling.

However, in existing smoothing filtering technologies (for example, moving average filter, double moving average filter, exponential moving average filter or one-dimensional gaussian filter), in order to enhance the smoothing degree, the filtered signal may be delayed or distorted. Alternatively, a one-dimensional gaussian filter may cause boundary phenomenon due to real-time data corresponding to the center point, thereby resulting in signal delay or distortion.

For example, FIG. 4 is a schematic diagram of a gaussian filter according to an embodiment of the disclosure. Referring to FIG. 4, a one-dimensional gaussian filter (GF) eliminates high-frequency oscillations through weighted averaging while preserving edge information. Based on the normal distribution function, weighted coefficients are used to average the input data, giving higher weights to data closer to the center point. As shown in the figure, the weight at the center point is 1, and the weights decrease as they move away from the center point. In a gaussian filter, the filter/window size and standard deviation are important parameters. The filter/window size determines the coverage of the convolution operation, while the standard deviation affects the distribution of weighting coefficients; adjusting the standard deviation can control the degree of smoothing. A one-dimensional gaussian filter calculates weighting coefficients through mathematical formulas and applies them in convolution operations. The formula for a one-dimensional gaussian filter is as follows:

$$ω = \frac{1}{σ \sqrt{2 π}} exp ( - \frac{{( x - μ )}^{2}}{2 {σ}^{2}} ) , \qquad ( 2 )$$

where ω is the weighting coefficient, μ represents the center position of the filter, σ represents the standard deviation of the filter, and x represents the input data to be filtered.

However, when the center point of the filter is updated data (for example, the latest output power), there is no data for the right half relative to the center point (corresponding to the extended time interval or future time interval). In current industry practice, the right half data is automatically filled with zeros (as shown in FIG. 4). This approach causes the value after smoothing through the gaussian filter to be smaller than the original value, resulting in time delay phenomenon and distortion. Due to the missing edge data, the smoothing effect of the filter is affected, and this becomes more obvious as the filter width or window width increases, leading to decreased accuracy of processing results, and even abnormal oscillation problems. Therefore, if the one-dimensional gaussian filter is not improved, there is no advantage for real-time calculation.

In one embodiment, the controller 110 may set the second output power greater than zero. Compared to setting it to zero, a second output power greater than zero will make the value after gaussian filter smoothing closer to the original value.

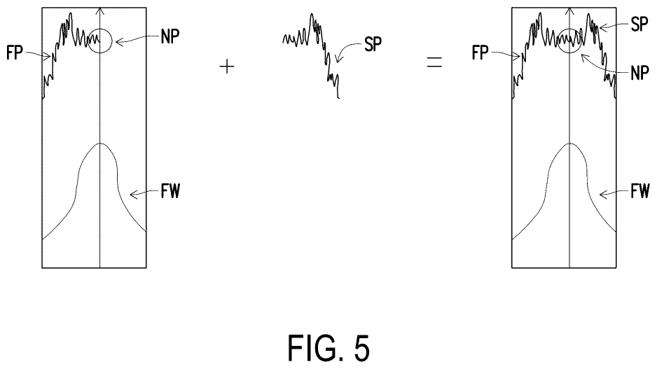

In one embodiment, the second output power is generated according to the first output power. For example, FIG. 5 is a schematic diagram of signal expansion according to an embodiment of the disclosure. Referring to FIG. 5, the controller 110 may determine a first signal waveform of a first output power FP within the monitoring time interval. The first signal waveform is the amplitude shape of the first output power FP as it varies with time within the monitoring time interval.

In addition, the controller 110 may generate a second signal waveform according to the first signal waveform. The second signal waveform may represent the amplitude shape of a second output power SP as it varies with time within the extended time interval.

In one embodiment, the controller 110 may use the mirror-flipped first signal waveform as the second signal waveform. With the vertical axis through a latest output power NP of the first output power FP (for example, the axis corresponding to amplitude/power magnitude) as the center axis, the controller 110 flips the first signal waveform from left to right (assuming the left half corresponds to the monitoring time interval, and the right half corresponds to the extended time interval), thereby generating the second signal waveform.

Subsequently, the controller 110 may determine the second output power SP according to the second signal waveform. For example, multiple second power values at multiple sample points are set to the amplitude at corresponding time points on the second signal waveform.

This embodiment proposes an Improved Gaussian Filter (IGF) FW, and one of its multiple purposes is to improve the traditional one-dimensional gaussian filter. The filter/window size and standard deviation remain important input calculation parameters for obtaining weight distribution. For boundary processing, it uses mirror compensation method (also known as symmetric expansion method or reflection expansion method) to solve boundary problems, thereby improving the defects of time delay phenomenon. By mirroring the boundary of the original signal (i.e., the first signal waveform) symmetrically, and expanding data opposite to the original signal at the boundary, an expanded signal (i.e., the second signal waveform) is generated, and the gaps in the original filter size are filled.

For example,

$$\tilde{x} = \{ \begin{matrix}x [ L - n - 1 ] , if n < L \\ x [ n ] , if L \leq n < N + L \\ x [ 2 N - n - 1 ] , if n \geq N + L\end{matrix} , \qquad ( 3 )$$

where x is an original signal (e.g., a signal of the first output power during the monitoring time interval), \tilde{x} is an expanded signal (e.g., a combination of a signal of the first output power during the monitoring time interval and a signal of the second output power during the extended time interval), L is the number of sampling points of the extended range (e.g., extended time interval), and N is the length of the original signal (e.g., the number of sampling points of the monitoring time interval). In other words, the L first power values on the left side relative to the center point are mirrored and filled into the L second power values on the right side relative to the center point to complement the complete Gaussian window signal. In this way, the edge effect can be avoided in the signal filtering, the influence of the edge effect on the calculation result can be effectively reduced, and the accuracy of the signal processing can be improved.

In one embodiment, the center point of the weight distribution of the improved gaussian filter FW corresponds to the latest output power NP of the first output power FP in the monitoring time interval, and the window size of the improved gaussian filter FW corresponds to/equals/is approximately the sum of the monitoring time interval and the extended time interval. For example, if the monitoring time interval is a time interval corresponding to 10 first power values, and the extended time interval is a time interval corresponding to 9 second power values, then the window size is 19.

In another embodiment, the center point of the weight distribution of the improved gaussian filter FW corresponds to other output power values of the first output power FP in the monitoring time interval, and/or the window size of the improved gaussian filter FW is smaller than the sum of the monitoring time interval and the extended time interval. For example, the center point corresponds to the first power value of the second-to-last sample point. For another example, if the monitoring time interval is a time interval corresponding to 8 first power values, and the extended time interval is a time interval corresponding to 7 second power values, then the window size is 13.

Referring to FIG. 3, the controller 110 determines the filter weight based on the first output power and the second output power (step S330), and smooths the first output power and the second output power based on the filter weight (step S340). Specifically, the filter weight is used for smooth filtering. Smooth filtering uses the filter weight to perform weighted calculations on the power values of the first output power and the second output power. As shown in the gaussian filter in FIG. 4, the input data [4 3 1 4 6] are weighted with the filter weight [0.1 0.3 1 0.3 0.1] respectively to obtain the smoothed output power corresponding to the center point (for example, the latest output power).

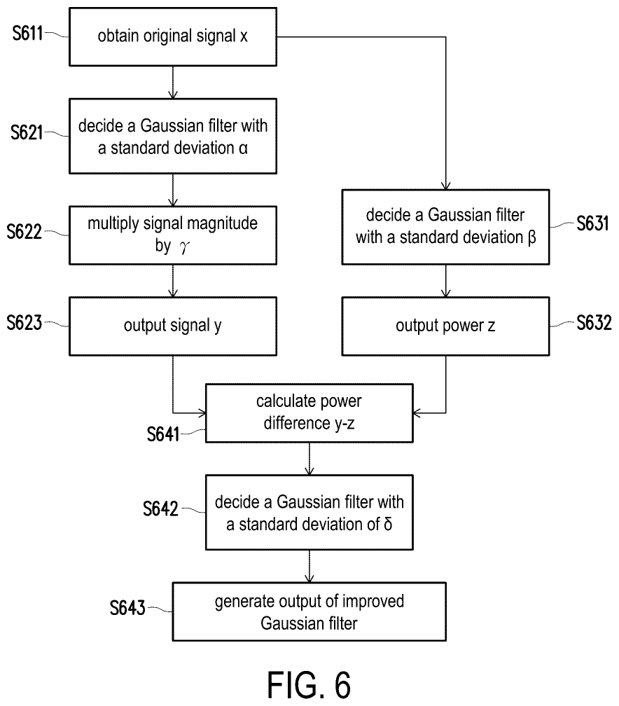

FIG. 6 is a flowchart of improved gaussian filter smoothing according to an embodiment of the disclosure. Referring to FIG. 6, the improved Gaussian filter includes a first filter, a second filter, and a third filter. The controller 110 may obtain an original signal x (e.g., a signal of a first output power during a monitoring time interval) (step S611).

The controller 110 may determine a (first) filter with a standard deviation of α (Step S621). α is σ/n, n is a positive integer between 2 and 5, and σ is the standard deviation of the original signal x at the Gaussian filter (e.g., the standard deviation of the first output power against the Gaussian filter). The controller 110 may smooth the original signal x (i.e., the signal of the first output power) through the first filter and generate the third output power. Next, the controller 110 multiplies the signal of the third output power by γ times (step S622), and generates a fourth output power. γ is a value between 2 and 4. Next, the controller 110 outputs a signal y (i.e., a signal of the fourth output power) (Step S623).

On the other hand, the controller 110 may determine a (second) filter with a standard deviation of β (step S631). β is σ. i.e., the same as the standard deviation of the original signal x in the Gaussian filter. The controller 110 may smooth the original signal x (i.e., the signal of the first output power) through the second filter and generate the fifth output power. Next, the controller 110 outputs a signal z (i.e., a signal of the fifth output power) (Step S632).

The controller 110 may calculate a power difference (y−z) between the signal y (i.e., the signal of the fourth output power) and the fifth output power z (i.e., the signal of the fifth output power) (step S641). The controller 110 may determine the smoothed output power (e.g., the output power smoothed by the improved gaussian filter of the latest output power) based on this power difference.

The controller 110 may determine a (third) filter with a standard deviation of δ (step S642). δ is σ/m, and m is a positive integer between 2 and 5. The controller 110 may smooth the signal of the power difference through the third filter, and generate the output of the improved gaussian filter (i.e., the smoothed output power) (step S643).

In an embodiment, n is 2, γ is 4, and m is 2. Thereby, it may correspond to the embodiment shown in FIG. 5. That is, the center point of the weight distribution of the improved gaussian filter FW corresponds to the latest output power NP of the first output power FP in the monitoring time interval, and the window size of the improved gaussian filter FW corresponds to the sum of the monitoring time interval and the extended time interval.

However, the parameters used by the improved gaussian filter may still be adjusted according to actual requirements.

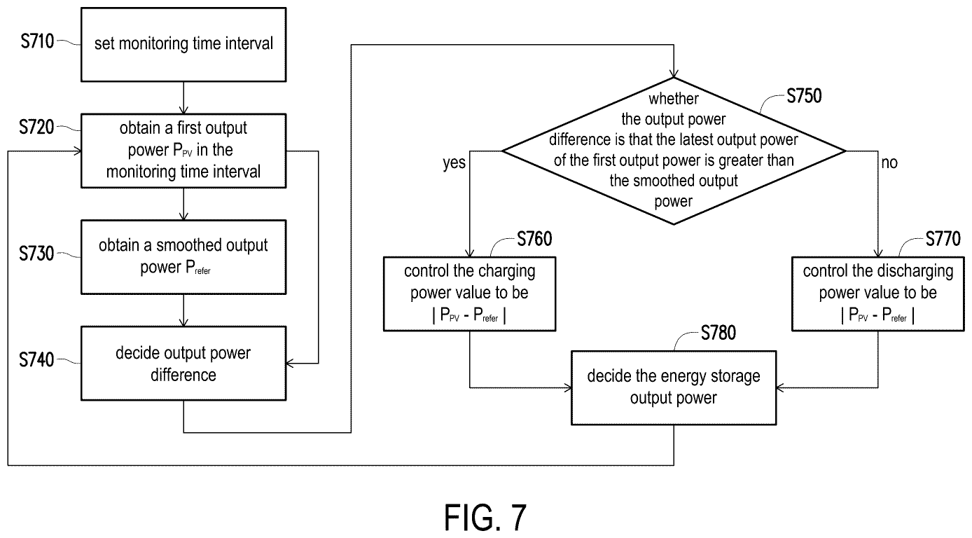

FIG. 7 is a flowchart of energy storage power control according to an embodiment of the disclosure. Referring to FIG. 7, the controller 110 may set a monitoring time interval (step S710). As introduced in step S310, and the length of the monitoring time interval may be defined according to actual requirements, which will not be repeated in the following. The controller 110 may obtain a first output power P_{PV} in the monitoring time interval (step S720), as introduced in step S310, which will not be repeated in the following. For example, capturing the power value sent from solar energy to the electricity network. The controller 110 may obtain a smoothed output power P_{refer} (step S730), as introduced in steps S330 to S340, which will not be repeated in the following.

Next, the controller 110 may determine an output power difference between the latest output power in the first output power and the smoothed output power (step S740). As explained above, the latest output power is the last sampling value of the first output power in the monitoring time interval, and the smoothed output power is the smoothed output power of the first output power and the second output power. The controller 110, for example, subtracts the smoothed output power from the latest output power to obtain the output power difference, for example, the first output power P_{PV}—the smoothed output power P_{refer}.

The controller 110 may determine the energy storage output power of the energy storage device 120 based on the output power difference. The storage output power is one of a charging power value and a discharging power value. The charging power value corresponds to a charging operation, for example, charging the energy storage device 120 with electricity provided by the electricity supply system 50. The discharging power value corresponds to a discharging operation, for example, providing electricity to a coupled electricity network or other electricity system.

The controller 110 may generate a control command for the energy storage output power. This control command is used to instruct the energy storage device 120 to perform the corresponding charging operation or discharging operation. In response to the control command indicating a charging power value, the energy storage device 120 requests a charging operation with this charging power value from the electricity supply system 50 (for example, issuing a corresponding command). In response to the control command indicating a discharging power value, the energy storage device 120 performs a discharging operation with the indicated charging power value to the coupled electricity network or other electricity system.

Taking FIG. 7 as an example, the controller 110 determines whether the output power difference is that the latest output power of the first output power is greater than the smoothed output power (step S750), for example, whether the first output power P_{PV}—the smoothed output power P_{refer} is greater than zero.

In response to the latest output power being greater than the smoothed output power, the controller 110 controls the charging power value to be, for example, the absolute value of the first output power P_{PV}—the smoothed output power P_{refer} (step S760).

On the other hand, in response to the latest output power not being greater than the smoothed output power, the controller 110 controls the discharging power value to be, for example, the absolute value of the first output power P_{PV}—the smoothed output power P_{refer} (step S770).

Next, the controller 110 determines the energy storage output power (step S780). For example, in response to the latest output power being greater than the smoothed output power, the controller 110 determines the energy storage output power to be the charging power value, and controls the energy storage device 120 to perform a charging operation with the specified charging power value. Alternatively, in response to the latest output power not being greater than the smoothed output power, the controller 110 determines the energy storage output power to be the discharging power value, and controls the energy storage device 120 to perform a charging operation with the specified discharging power value.

In an application scenario, an energy storage system (corresponding to the energy storage device 120), a solar photovoltaic system (corresponding to the electricity supply system 50), and loads are integrated into a three-zone microgrid system. Through the smoothing control of the embodiment of this disclosure, the output power of the three-zone microgrid is integrated, making the overall output of the three-zone microgrid system back to the utility power end effectively smoothed and compliant with the variation rate of output stipulated by the electricity company. Through the obtained distribution ratio, the battery power of the three-zone microgrid can be effectively balanced and kept consistent. This control strategy not only effectively improves the electricity quality at the utility power end but also maintains the balance of power, thereby increasing the usage time of the overall electricity network.

The embodiment of this disclosure proposes an improved gaussian filtering algorithm, and compares the smoothing effect on time-varying data with common smoothing filtering methods, through graphical judgment of the differences between different filtering methods after smoothing, and may be used to evaluate the performance and benefits of different methods.

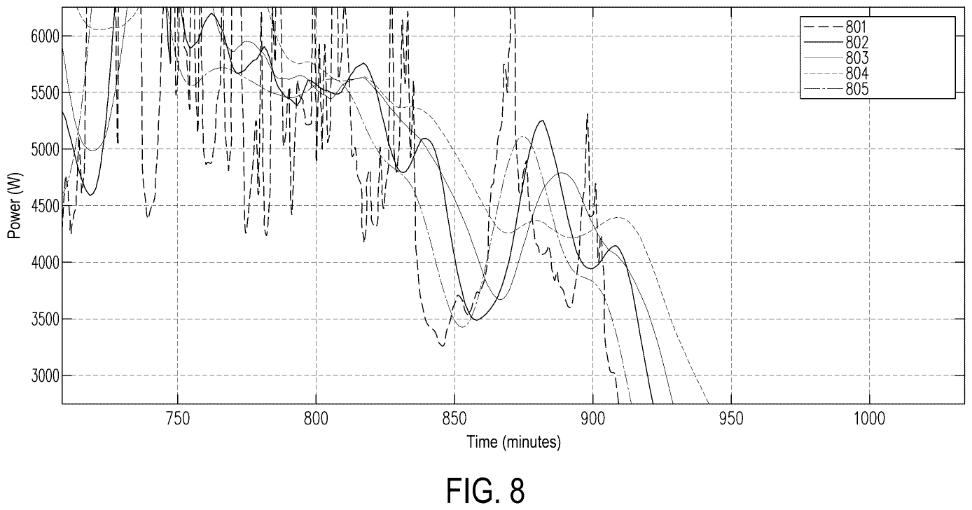

FIG. 8 is a comparison diagram of an improved gaussian filter 805 and moving average methods 802, 803, 804 of the embodiment of this disclosure. Referring to FIG. 8, compared with a real-time output power 801, although the moving average methods 802, 803, 804 with window sizes of 12, 24, and 48 respectively can all smooth the values, as the window size increases, the smoothing performance improves significantly. However, using the moving average method 804 with a window size of 48 may lead to a longer delay phenomenon, thereby causing the smoothed data to be significantly offset, resulting in relatively poor power tracking capability. The improved gaussian filter 805 also provides better smoothing effect and effectively reduces the time delay phenomenon.

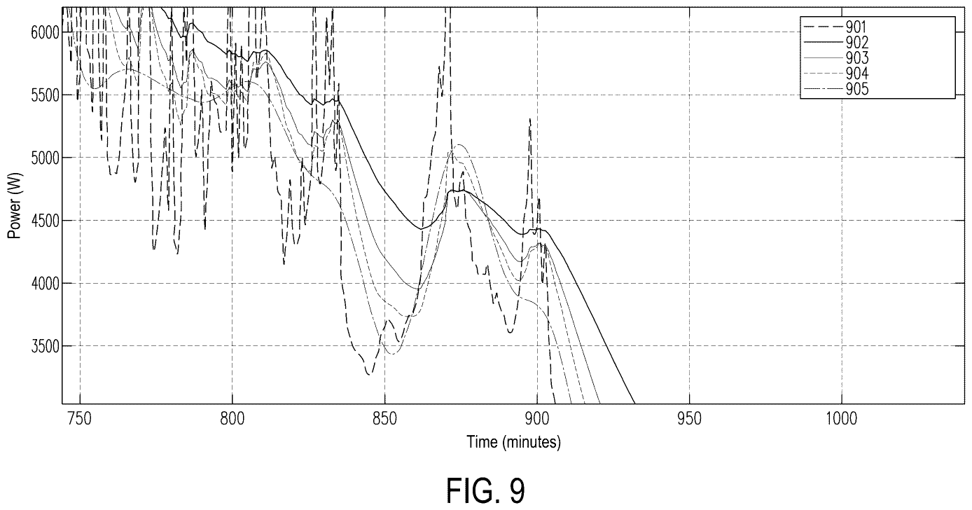

FIG. 9 is a comparison diagram of an improved gaussian filter 905 and double moving average methods 902, 903, 904 of the embodiment of this disclosure. Referring to FIG. 9, compared with a real-time output power 901, although the double moving average methods 902, 903, 904 with window sizes of (12, 12), (24, 12), and (48, 12) respectively can all smooth the values, as the window size increases, the smoothing performance improves significantly. However, the delay phenomenon is most severe when using the double moving average method 904 with a window size of (48, 12), which also causes the smoothed data to be significantly offset, and the power tracking capability is relatively poor. Similarly, the improved gaussian filter 905 also provides better smoothing effect and effectively reduces the time delay phenomenon.

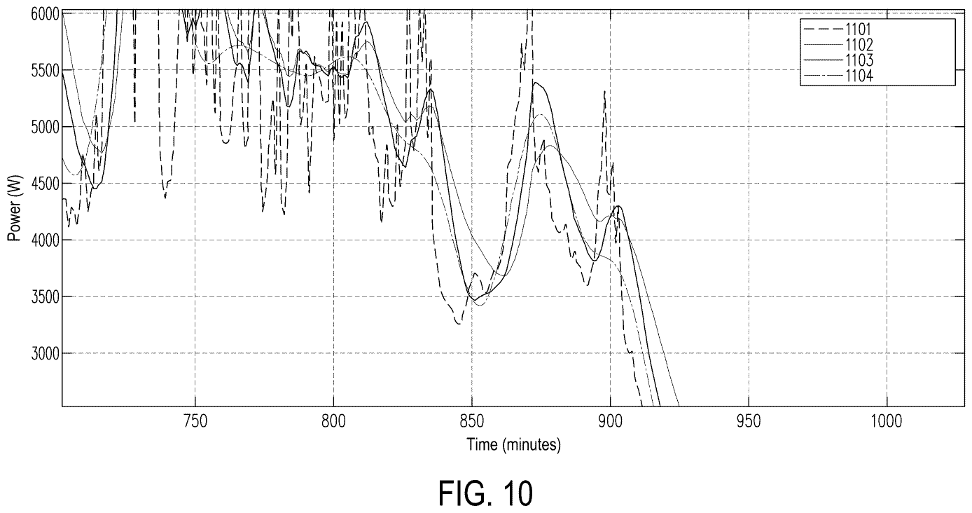

FIG. 10 is a comparison diagram of an improved gaussian filter 1104 and exponential moving average methods 1102, 1103 of the embodiment of this disclosure. Referring to FIG. 10, compared with a real-time output power 1101, although the exponential moving average methods 1102 and 1103 with smoothing coefficients of 0.03, 0.06, and 0.1 respectively can all smooth the values, as the smoothing coefficient decreases, the smoothing performance improves. However, the exponential moving average method 1102 with a smoothing coefficient of 0.03 has a slower response to the rise or fall of the real-time output power 1101, and the time delay phenomenon is also the most obvious and severe. Similarly, the improved gaussian filter 1104 also provides better smoothing effect and effectively reduces the time delay phenomenon.

In summary, in the energy control method and the controller for energy management of the embodiment of this disclosure, the boundary problem of smoothing filtering is addressed by expanding the output power after the monitoring time interval. In addition, by mirroring the boundaries of the original signal of the first output power within the monitoring time, and expanding data opposite to the original signal at the boundaries, an extended signal is generated, and the gaps of the original filter size are filled. Thereby, the degree of smoothing control may be improved and time delay may be reduced.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. An energy control method, comprising:
obtaining a first output power of a target energy source in a monitoring time interval;
determining a second output power of the target energy source in an extended time interval, wherein the extended time interval corresponds to a time interval after the monitoring time interval;
determining a filter weight according to the first output power and the second output power, wherein the filter weight is configured to smooth filtering; and
smoothing the first output power and the second output power according to the filter weight.

2. The energy control method according to claim 1, wherein determining the second output power of the target energy source in the extended time interval comprises:
setting the second output power greater than zero.

3. The energy control method according to claim 1, wherein determining the second output power of the target energy source in the extended time interval comprises:
determining a first signal waveform of the first output power in the monitoring time interval;
generating a second signal waveform according to the first signal waveform; and
determining the second output power according to the second signal waveform.

4. The energy control method according to claim 3, wherein generating the second signal waveform according to the first signal waveform comprises:
using the first signal waveform that is mirror-flipped as the second signal waveform.

5. The energy control method according to claim 1, wherein determining the filter weight according to the first output power and the second output power comprises:
determining the filter weight through an improved gaussian filter, wherein a center point of weight distribution of the improved gaussian filter corresponds to a latest output power of the first output power in the monitoring time interval, and a window size of the improved gaussian filter corresponds to a sum of the monitoring time interval and the extended time interval.

6. The energy control method according to claim 5, wherein the improved gaussian filter comprises a first filter and a second filter, and determining the filter weight through the improved gaussian filter comprises:
determining the first filter with a standard deviation of α, wherein α is σ/n, n is a positive integer between 2 and 5, and σ is a standard deviation of a gaussian filter corresponding to the first output power; and
determining the second filter with a standard deviation of β, wherein β is σ.

7. The energy control method according to claim 6, wherein smoothing the first output power and the second output power according to the filter weight comprises:
smoothing a signal of the first output power through the first filter, and generating a third output power;
multiplying a signal of the third output power by γ times, and generating a fourth output power, wherein γ is a value between 2 and 4;
smoothing a signal of the first output power through the second filter, and generating a fifth output power;
calculating a power difference between the fourth output power and the fifth output power; and
determining a smoothed output power according to the power difference.

8. The energy control method according to claim 7, wherein the improved gaussian filter further comprising a third filter, and determining the filter weight through the improved gaussian filter comprises:
determining the third filter with a standard deviation of δ, wherein δ is σ/m, and m is a positive integer between 2 and 5.

9. The energy control method according to claim 8, wherein determining the smoothed output power according to the power difference comprises:
smoothing a signal of the power difference through the third filter, and generating the smoothed output power.

10. The energy control method according to claim 1, further comprising:
determining an output power difference between a latest output power and a smoothed output power, wherein the latest output power is a last sampling value of the first output power in the monitoring time interval, and the smoothed output power is a smoothed output power of the first output power and the second output power; and
determining an energy storage output power according to the output power difference, wherein the energy storage output power is one of a charging power value and a discharging power value.

11. A controller for energy management, configured to:
obtain a first output power of a target energy source in a monitoring time interval;
determine a second output power of the target energy source in an extended time interval, wherein the extended time interval corresponds to a time interval after the monitoring time interval;
determine a filter weight according to the first output power and the second output power, wherein the filter weight is configured to smooth filtering; and
smooth the first output power and the second output power according to the filter weight.

12. The controller for energy management according to claim 11, further configured to:
set the second output power greater than zero.

13. The controller for energy management according to claim 11, further configured to:
determine a first signal waveform of the first output power in the monitoring time interval;
generate a second signal waveform according to the first signal waveform; and
determine the second output power according to the second signal waveform.

14. The controller for energy management according to claim 13, further configured to:
use the first signal waveform that is mirror-flipped as the second signal waveform.

15. The controller for energy management according to claim 11, further configured to:
determine the filter weight through an improved gaussian filter, wherein a center point of weight distribution of the improved gaussian filter corresponds to a latest output power of the first output power in the monitoring time interval, and a window size of the improved gaussian filter corresponds to a sum of the monitoring time interval and the extended time interval.

16. The controller for energy management according to claim 15, wherein the improved gaussian filter comprises a first filter and a second filter, and the controller is further configured to:
determine the first filter with a standard deviation of α, wherein α is σ/n, n is a positive integer between 2 and 5, and σ is a standard deviation of α gaussian filter corresponding to the first output power; and
determine the second filter with a standard deviation of β, wherein β is σ.

17. The controller for energy management according to claim 16, further configured to:
smooth a signal of the first output power through the first filter, and generate a third output power;
multiply a signal of the third output power by γ times, and generate a fourth output power, wherein γ is a value between 2 and 4;
smooth a signal of the first output power through the second filter, and generate a fifth output power;
calculate a power difference between the fourth output power and the fifth output power; and
determine a smoothed output power according to the power difference.

18. The controller for energy management according to claim 17, wherein the improved gaussian filter further comprises a third filter, and the controller is further configured to:
determine the third filter with a standard deviation of δ, wherein δ is σ/m, and m is a positive integer between 2 and 5.

19. The controller for energy management according to claim 18, further configured to:
smooth a signal of the power difference through the third filter, and generate the smoothed output power.

20. The controller for energy management according to claim 11, further configured to:
determine an output power difference between a latest output power and a smoothed output power, wherein the latest output power is a last sampling value of the first output power in the monitoring time interval, and the smoothed output power is a smoothed output power of the first output power and the second output power;
determine an energy storage output power according to the output power difference, wherein the energy storage output power is one of a charging power value and a discharging power value; and
generate a control command according to the energy storage output power.
